(19) United States
(12) Patent Application Publication
(10) Pub. No.: US 2025/0357722 A1
(43) Pub. Date: Nov. 20, 2025

(54) OPTICAL INTEGRATED DEVICE, SEMICONDUCTOR OPTICAL DEVICE AND SEMICONDUCTOR OPTICAL DEVICE MANUFACTURING METHOD

(71) Applicant: FURUKAWA ELECTRIC CO., LTD., Tokyo (JP)

(72) Inventors: Masahiko SHIRAISHI, Tokyo (JP); Masahiro YOSHIDA, Tokyo (JP); Kazuaki KIYOTA, Tokyo (JP)

(73) Assignee: FURUKAWA ELECTRIC CO., LTD., Tokyo (JP)

(21) Appl. No.: 19/282,091

(22) Filed: Jul. 28, 2025

Related U.S. Application Data
(63) Continuation of application No. PCT/JP2024/002928, filed on Jan. 30, 2024.

(30) Foreign Application Priority Data
Jan. 30, 2023 (JP) 2023-011501

(51) Int. Cl. H01S 5/026

(52) U.S. Cl. CPC H01S 5/026

(57) ABSTRACT

A semiconductor optical device includes: a first layered portion including therein a first waveguide; a first top surface positioned at a first end portion of the first layered portion; a first end surface positioned at a second end portion of the first layered portion; a plurality of first end portions of the first waveguide, the plurality of first end portions being exposed at a plurality of positions on the first end surface; two first position identification marks provided on the first top surface; and a first orientation identification mark provided on the first top surface.

This application is a continuation of International Application No. PCT/JP2024/002928, filed on Jan. 30, 2024 which claims the benefit of priority of the prior Japanese Patent Application No. 2023-011501, filed on Jan. 30, 2023, the entire contents of which are incorporated herein by reference.

### BACKGROUND

The present disclosure relates to an optical integrated device, a semiconductor optical device and a semiconductor optical device manufacturing method.

In the related art, a semiconductor optical integrated device is known that includes, in an integrated manner, a semiconductor optical device, such as a semiconductor laser device or a semiconductor optical amplifier, and a portion including waveguides (hereinafter, that portion is referred to as an optical function device) (for example, refer to Japanese Patent Application Laid-open No. 2017-92262).

### SUMMARY

In a semiconductor optical device of the abovementioned type, in order to achieve the required optical coupling efficiency between the waveguides of the semiconductor optical device and the waveguides of the optical function device, the alignment between the semiconductor optical device and the optical function device is an important factor.

As far as alignment marks for enabling the abovementioned alignment are concerned, for example, if it becomes possible to obtain alignment marks that enable accurate alignment regardless of the manufacturing variation, it would be beneficial.

Three is a need for a semiconductor optical device that includes new and improved alignment marks, and to obtain a semiconductor optical device manufacturing method.

According to one aspect of the present disclosure, there is provided an optical integrated device including: a semiconductor optical device; and an optical function device, wherein the semiconductor optical device includes: a first layered portion including therein a first waveguide extending in a direction intersecting with a first direction; a first top surface positioned at a first end portion of the first layered portion in the first direction, the first top surface intersecting with the first direction and being oriented in the first direction; a first end surface positioned at a second end portion of the first layered portion in a second direction intersecting with the first direction, the first end surface intersecting with the second direction and being oriented in the second direction; a plurality of first end portions of the first waveguide, the plurality of first end portions being exposed at a plurality of positions on the first end surface and separated from each other in a third direction intersecting with the first direction and the second direction; two first position identification marks provided on the first top surface and separated from each other in the third direction such that the two first position identification marks extend in parallel to a direction of extension of the first end portions at the first end surface from an end portion of the first top surface in the second direction and are positioned in between the plurality of first end portions when viewed from opposite direction of the first direction, and a predetermined relative positional relationship is established with the plurality of first end portions in the third direction; and a first orientation identification mark provided on the first top surface and configured to enable identification of the third direction in the first layered portion when viewed from an opposite direction of the first direction, and the optical function device includes: a second layered portion including therein a second waveguide extending in a direction intersecting with the first direction; a second top surface positioned at an end portion of the second layered portion in the first direction, the second top surface intersecting with the first direction and being oriented in the first direction; a second end surface that is positioned at a third end portion of the second layered portion in an opposite direction of the second direction, the second end surface intersecting with the second direction and being oriented in the opposite direction of the second direction; a plurality of second end portions of the second waveguide, the plurality of second end portions being exposed at a plurality of positions of the second end surface and separated from each other in the third direction such that intervals therebetween correspond to intervals between the plurality of first end portions; two second position identification marks provided on the second top surface and separated from each other in the third direction such that the two second position identification marks extend in parallel to a direction of extension of the second end portions at the second end surface from an end portion of the second top surface in the opposite direction of the second direction and are positioned in between the plurality of second end portions when viewed from an opposite direction of the first direction, and relative positional relationship established therebetween is same as relative positional relationship established between the plurality of first end portions and the two first position identification marks in the third direction; and a second orientation identification mark provided on the second top surface and configured to enable identification of the third direction in the second layered portion when viewed from the opposite direction of the first direction.

According to another aspect of the present disclosure, there is provided a semiconductor optical device including: a first layered portion including therein a first waveguide extending in a direction intersecting with a first direction; a first top surface positioned at a first end portion of the first layered portion in the first direction, the first top surface intersecting with the first direction and being oriented in the first direction; a first end surface positioned at a second end portion of the first layered portion in a second direction intersecting with the first direction, the first end surface intersecting with the second direction and being oriented in the second direction; a plurality of first end portions of the first waveguide, the plurality of first end portions being exposed at a plurality of positions on the first end surface and separated from each other in a third direction intersecting with the first direction and the second direction; two first position identification marks provided on the first top surface and separated from each other in the third direction such that the two first position identification marks extend in parallel to a direction of extension of the first end portions at the first end surface from an end portion of the first top surface in the second direction and are positioned in between the plurality of first end portions when viewed from opposite direction of the first direction, and a predetermined relative positional relationship is established with the plurality of first end portions in the third direction; and a first orientation identification mark provided on the first top surface and configured to enable identification of the third direction in the first layered portion when viewed from an opposite direction of the first direction.

According to still another aspect of the present disclosure, there is provided a method for manufacturing a semiconductor optical device for an optical integrated device including the semiconductor optical device and an optical function device, wherein the semiconductor optical device includes: a first layered portion including therein a first waveguide extending in a direction intersecting with a first direction; a first top surface positioned at a first end portion of the first layered portion in the first direction, the first top surface intersecting with the first direction and being oriented in the first direction; a first end surface positioned at a second end portion of the first layered portion in a second direction intersecting with the first direction, the first end surface intersecting with the second direction and being oriented in the second direction; a plurality of first end portions of the first waveguide, the plurality of first end portions being exposed at a plurality of positions on the first end surface and separated from each other in a third direction intersecting with the first direction and the second direction; two first position identification marks provided on the first top surface and separated from each other in the third direction such that the two first position identification marks extend in parallel to a direction of extension of the first end portions at the first end surface from an end portion of the first top surface in the second direction and are positioned in between the plurality of first end portions when viewed from opposite direction of the first direction, and a predetermined relative positional relationship is established with the plurality of first end portions in the third direction; and a first orientation identification mark provided on the first top surface and configured to enable identification of the third direction in the first layered portion when viewed from an opposite direction of the first direction, and the optical function device includes: a second layered portion including therein a second waveguide extending in a direction intersecting with the first direction; a second top surface positioned at an end portion of the second layered portion in the first direction, the second top surface intersecting with the first direction and being oriented in the first direction; a second end surface that is positioned at a third end portion of the second layered portion in an opposite direction of the second direction, the second end surface intersecting with the second direction and being oriented in the opposite direction of the second direction; a plurality of second end portions of the second waveguide, the plurality of second end portions being exposed at a plurality of positions of the second end surface and separated from each other in the third direction such that intervals therebetween correspond to intervals between the plurality of first end portions; two second position identification marks provided on the second top surface and separated from each other in the third direction such that the two second position identification marks extend in parallel to a direction of extension of the second end portions at the second end surface from an end portion of the second top surface in the opposite direction of the second direction and are positioned in between the plurality of second end portions when viewed from an opposite direction of the first direction, and relative positional relationship established therebetween is same as relative positional relationship established between the plurality of first end portions and the two first position identification marks in the third direction; and a second orientation identification mark provided on the second top surface and configured to enable identification of the third direction in the second layered portion when viewed from the opposite direction of the first direction, the semiconductor optical device manufacturing method including: layering the first layered portion on a substrate; and forming, in the first layered portion, first depressed portions that are adjacent to both sides of a mesa including the first waveguide in the third direction and that are depressed in an opposite direction of the first direction, and second depressed portions that are depressed in the opposite direction of the first direction up to a same depth as a depth of the first depressed portions and that constitute the first position identification marks.

### BRIEF DESCRIPTION OF THE DRAWINGS

FIG. 1 is an illustrative and schematic planar view of an optical integrated device according to a first embodiment;

FIG. 2 is an illustrative and schematic planar view of some portion of the optical integrated device according to the first embodiment;

FIG. 3 is an illustrative and schematic planar view of different portions of the optical integrated device according to the first embodiment than the portions illustrated in FIG. 2, and is a diagram illustrating the difference in the relative position of the position of a semiconductor optical device with respect to an optical function device according to the variation in the position of the end portion of the semiconductor optical device;

FIG. 4 is an IV-IV cross-sectional view of FIG. 1;

FIG. 5 is a flowchart for explaining some part of the sequence of manufacturing the semiconductor optical device according to the first embodiment;

FIG. 6 is an illustrative and schematic cross-sectional view, of an equivalent position to FIG. 4, of a semiconductor optical device according to a second embodiment;

FIG. 7 is an illustrative and schematic planar view of some part of an optical integrated device according to a third embodiment;

FIG. 8 is an illustrative and schematic planar view of some part of an optical integrated device according to a fourth embodiment;

FIG. 9 is an illustrative and schematic planar view of some part of an optical integrated device according to a fifth embodiment; and

FIG. 10 is an illustrative and schematic planar view of an optical integrated device according to a sixth embodiment.

### DETAILED DESCRIPTION

Exemplary embodiments are described below. The configurations explained in the embodiments described below as well as the actions and the results (effects) attributed to the configurations are only exemplary. Thus, the present disclosure may be implemented also using some different configuration than the configurations disclosed in the embodiments described below. Meanwhile, according to the present disclosure, it becomes possible to achieve at least one of various effects (including secondary effects) that are attributed to the configurations.

The embodiments described below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating among the directions and the portions. Thus, the ordinal numbers neither indicate the priority or the sequencing nor restrict the count.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. The Z direction is referred to as the layering direction or the height direction.

Meanwhile, the drawings are schematic diagrams intended for use in the explanation. Thus, in the drawings, the scale and the ratio does not necessarily match with the actual objects.

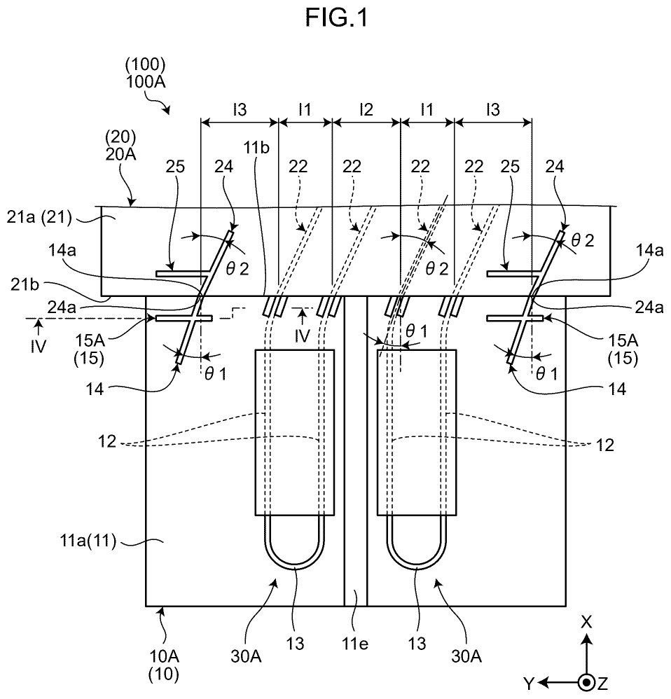

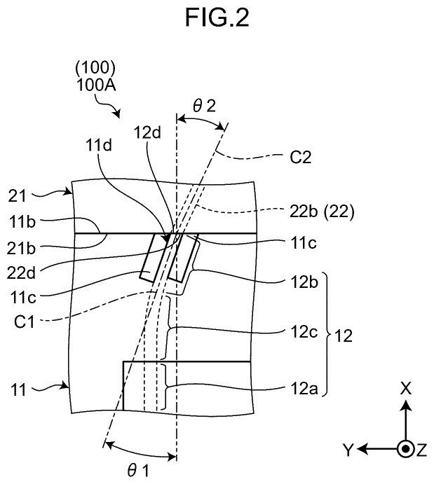

FIG. 1 is a planar view of an optical integrated device 100A (100). FIG. 2 is an enlarged view of some portion of FIG. 1. As illustrated in FIG. 1, the optical integrated device 100A (100) includes a semiconductor optical device 10A (10) and an optical function device 20A (20). The semiconductor optical device 10 and the optical function device 20 are integrated in the state in which an end surface 11b of the semiconductor optical device 10 in the X direction and an end surface 21b of the optical function device 20 in the opposite direction of the X direction either are facing each other with a minute gap therebetween or are making contact with each other. On the end surface 11b, a plurality of end surfaces 12d of waveguides 12 (see FIG. 2) are exposed. Similarly, on the end surface 21b, a plurality of end surfaces 22d of waveguides 22 (see FIG. 2) are exposed. The semiconductor optical device 10 and the optical function device 20 are integrated in the state in which alignment marks 14 and 15, which are provided in the semiconductor optical device 10, and alignment marks 24 and 25, which are provided in the optical function device 20, are aligned in such a way that the end surfaces 12d and the end surfaces 22d remain oriented in the X direction without straying in the Y direction as much as possible.

As illustrated in FIG. 1, the semiconductor optical device 10 has a top surface 11a and an end surface 11b. The top surface 11a is positioned at the end portion of a layered portion 11 in the Z direction, intersects with the Z direction, and is oriented in the Z direction. The end surface 11b is positioned in the end portion of the layered portion 11 in the X direction, intersects with the X direction, and is oriented in the X direction. The layered portion 11 represents an example of a first layered portion. The top surface 11a represents an example of a first top surface. The end surface 11b represents an example of a first end surface. The Z direction represents an example of a first direction. The X direction represents an example of a second direction.

Inside the layered portion 11, a plurality of waveguides 12 is formed. In the state in which intervals I1 and I2 are constant in the Y direction, the waveguides 12 extend in the X direction. The waveguides 12 represent examples of a first waveguide. The Y direction represents an example of a third direction. As long as the waveguides 12 extend in a direction intersecting with the Z direction, it serves the purpose. Thus, the waveguides 12 are not limited to extend in the X direction.

The waveguides 12 represent the core layers formed inside a cladding layer or a current prevention layer. The cladding layer or the current prevention layer is made of, for example, n-InP and p-InP. The core layer is made of, for example, GaInAsP. In the layered portion 11, the cladding layer or the current prevention layer encloses the periphery of the core layer.

In the first embodiment, each set of two waveguides 12 are optically coupled with each other via a waveguide 13 that is formed in a U-shape when viewed from the opposite direction of the Z direction. The two waveguides 12, which are optically coupled with each other, and the waveguide 13 constitute a waveguide structure assembly 30A. In the first embodiment, the layered portion 11 includes two such waveguide structure assemblies 30A. In the layered portion 11, in between the two waveguide structure assemblies 30A, a trench 11e is formed that is depressed from the top surface 11a toward the opposite direction of the Z direction and that extends in the X direction. The waveguides 13 represent examples of a folded waveguide.

Each waveguide structure assembly 30A may be configured as, for example, a semiconductor optical amplifier. In that case, the waveguides 12 are configured as active waveguides, and the waveguide 13 are configured as a passive waveguide. Each waveguide structure assembly 30A performs optical amplification of the light input from the end surface 12d of one of the two waveguides 12 and outputs the amplified light from the end surface 12d of the other waveguide 12. In that case, the semiconductor optical device 10A functions as a semiconductor optical amplifier array.

As illustrated in FIG. 2, each waveguide 12 includes a straight portion 12a, an inclined portion 12b, and a curved portion 12c. The straight portion 12a extends in the X direction. The inclined portion 12b extends in the direction that is inclined from the end surface 11b by an angle θ1 with respect to the X direction. In the inclined portion 12b, the end surface 12d is exposed from the layered portion 11 at the end surface 11b. Meanwhile, a plurality of end surfaces 12d is separated from each other in the Y direction. The curved portion 12c smoothly joins the straight portion 12a and the inclined portion 12b. The inclined portions 12b represent examples of a first end portion.

As illustrated in FIG. 1, the optical function device 20 has a top surface 21a and an end surface 21b. The top surface 21a is positioned at the end portion of a layered portion 21 in the Z direction, intersects with the Z direction, and is oriented in the Z direction. The end surface 21b is positioned at the end portion of the layered portion 21 in the opposite direction of the X direction, intersects with the X direction, and is oriented in the opposite direction of the X direction. The layered portion 21 represents an example of a second layered portion. The top surface 21a represents an example of a second top surface. The end surface 21b represents an example of a second end surface.

Inside the layered portion 21, a plurality of waveguides 22 is formed. In the state in which the intervals I1 and I2 are constant in the Y direction, the waveguides 22 extend in the direction that is inclined by an angle θ2 with respect to the X direction. The end surfaces 22d of the waveguides 22 on the opposite side in the X direction are exposed from the end surface 21b of the layered portion 21. The end surfaces 22d are separated from each other in the Y direction. The waveguides 22 represent examples of a second waveguide. End portions 22b represent examples of a second end portion.

As is clear from FIG. 1, the end portions 22b and the intervals I1 and I2 between the end portions 22b in the Y direction are same as the inclined portions 12b of the waveguides 12 in the semiconductor optical device 10 and the intervals I1 and I2 of the end surfaces 12d (see FIG. 2) in the Y direction. That is, the end portions 22b are separated from each other in the Y direction and with the same intervals as the intervals between the corresponding inclined portions 12b. Thus, in the state in which the semiconductor optical device 10 and the optical function device 20 are correctly aligned, the end surfaces 12d of the waveguides 12 and the end surfaces 22d of the waveguides 22 happen to face each other.

Meanwhile, the reason for having the direction of extension of the inclined portions 12b of the waveguides 12 inclined by the angle θ1 with respect to the X direction and having the direction of extension of the end portions 22b of the waveguides 22 inclined by the angle θ2 with respect to the X direction is to hold down the situation in which the lights reflected from the end surfaces 11b and 21b get coupled in the waveguides 12 and 22. The angles θ1 and θ2 are appropriately set according to the refractive indexes of the constituent materials of the semiconductor optical device 10 and the optical function device 20.

As illustrated in FIGS. 1 and 2, on both sides of each inclined portion 12b, depressed portions 11c are formed that are depressed from the top surface 11a toward the opposite direction of the Z direction. That is, the inclined portion 12b at least partially includes a mesa 11d. The mesa 11d of the inclined portion 12b may be configured as, for example, a spot size converter that undergoes gradual variation in the width along the direction of extension.

As illustrated in FIG. 1, on the top surface 11a of the semiconductor optical device 10, the alignment marks 14 and 15A (15) are provided. Moreover, on the top surface 21a of the optical function device 20, the alignment marks 24 and 25 are provided.

In the semiconductor optical device 10, as the alignment marks 14, two alignment marks 14 are provided that are separated from each other in the Y direction. The alignment marks 14 extend from the end portion of the top surface 11a in the X direction toward the direction parallel to the direction of extension of the inclined portions 12b of the waveguides 12 (see FIG. 2). When viewed from the opposite direction of the Z direction, the two alignment marks 14 are provided in such a way that the inclined portions 12b of the waveguides 12 are positioned in between the two alignment marks 14. Moreover, the two alignment marks 14 are provided to have a predetermined relative positional relationship with the inclined portions 12b in the Y direction. More particularly, in the first embodiment, the interval to the closest inclined portion 12b in the Y direction is the interval I3; and the alignment mark 14, the four inclined portions 12b, and the other alignment mark 14 are provided in such a way that they are lined up with the intervals I3, I1, I2, I1, and I3 therebetween in the Y direction.

In the optical function device 20, as the alignment marks 24, two alignment marks 24 are provided that are separated from each other in the Y direction. The alignment marks 24 extend from the end portion of the top surface 21a in the X direction toward the direction parallel to the direction of extension of the end portions 22b of the waveguides 22 (see FIG. 2). When viewed from the opposite direction of the Z direction, the two alignment marks 24 are provided in such a way that the end portions 22b of the waveguides 22 are positioned in between the two alignment marks 24. Moreover, the two alignment marks 24 are provided to have a predetermined relative positional relationship with the end portions 22b in the Y direction. More particularly, in the first embodiment, the interval to the closest end portion 22b in the Y direction is the interval 13; and the alignment mark 24, the four end portions 22b, and the other alignment mark 24 are provided in such a way that they are lined up with the intervals I3, I1, I2, I1, and I3 therebetween in the Y direction. That is, as illustrated in FIG. 1, the arrangement of the alignment mark 24, the four end portions 22b, and the other alignment mark 24 in the Y direction and the arrangement of the alignment mark 14, the four end portions 12b, and the other alignment mark 14 in the Y direction have the same intervals I3, I1, I2, I1, and I3 therebetween, that is, have the same relative positional relationship.

Thus, the semiconductor optical device 10 and the optical function device 20 are aligned in the Y direction in such a way that end portions 14a of the alignment marks 14 in the X direction and end portions 24a of the alignment marks 24 in the opposite direction of the X direction are lined up in the X direction, that is, face in the X direction. As a result, it becomes possible to hold down the misalignment, in the Y direction, of the end surfaces 12d of the waveguides 12 (see FIG. 2) and the corresponding end surfaces 22d of the waveguides 22 (see FIG. 2), and to obtain the required optical coupling efficiency between the waveguides 12 and the waveguides 22. The alignment marks 14 represent examples of a first position identification mark, and the alignment marks 24 represent examples of a second position identification mark.

Moreover, as illustrated in FIG. 1, on the top surface 11a of the semiconductor optical device 10, the alignment marks 15A (15) are provided at positions separated from the end surface 11b and extend in the Y direction with a substantially constant width in the X direction. On the top surface 21a of the optical function device 20, the alignment marks 25 are provided at positions separated from the end surface 21b and extend in the Y direction with a substantially constant width in the X direction. When image processing of an image capturing the alignment marks 15 is performed or when the operator visually confirms an image capturing the alignment marks 15, it becomes possible to figure out the direction of extension of the alignment marks 15, that is, the Y direction. In other words, it becomes possible to figure out the orientation of the semiconductor optical device 10. Similarly, when image processing of an image capturing the alignment marks 25 is performed or when the operator visually confirms an image capturing the alignment marks 25, it becomes possible to figure out the direction of extension of the alignment marks 25, that is, the Y direction. In other words, it becomes possible to figure out the orientation of the optical function device 20. The alignment marks 15 represent examples of a first orientation identification mark, and the alignment marks 25 represent examples of a second orientation identification mark. The alignment marks 15 extend in the Y direction in whole, and the alignment marks 25 also extend in the Y direction in whole. The alignment marks 15 represent examples of a first extending portion.

With the configuration explained above, it becomes possible for an operator or a robot to maintain the alignment marks 15 and the alignment marks 25 parallel to the Y direction and at the same time to bring the end surface 11b and the end surface 21b closer to each other and to proportionally move the semiconductor optical device 10 and the optical function device 20 in the Y direction, so that the two alignment marks 14 and the corresponding two alignment marks 24 may be aligned to face in the X direction. That is, according to the first embodiment, the state in which the waveguides 12 and the waveguides 22 are facing in the X direction and are aligned with more accuracy may be attained more easily or more promptly.

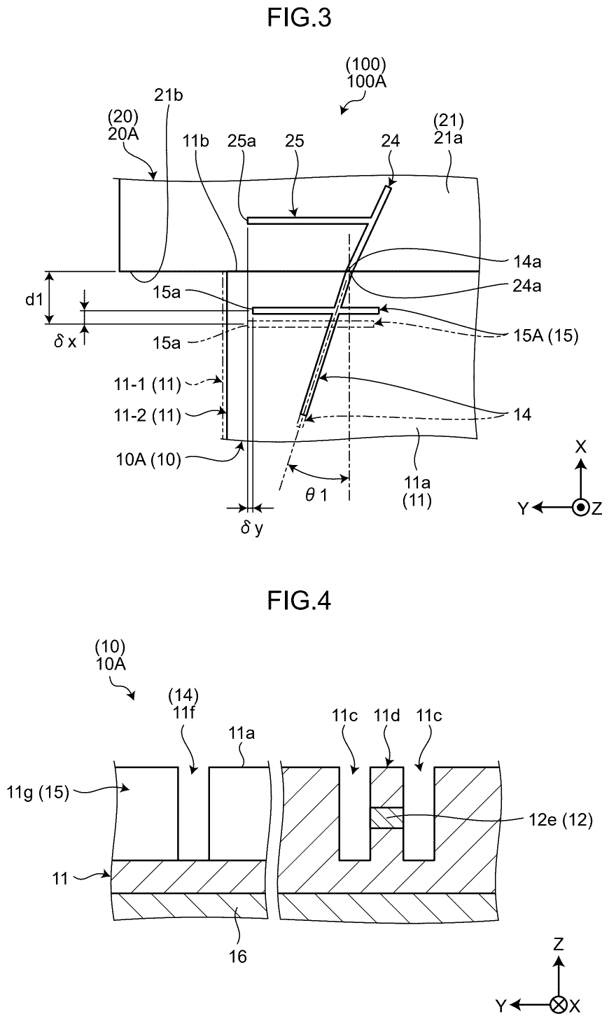

FIG. 3 is a planar view of different portions than the portions illustrated in FIGS. 1 and 2. In FIG. 3 are illustrated two layered portions 11-1 and 11-2 (11) in which the positions of the end surfaces 11b are different due to the manufacturing variation. In FIG. 3, the shape of the layered portion 11-1 is illustrated using a dash-dot-dot line, and the shape of the layered portion 11-2 is illustrated using a solid line. In FIG. 3 is illustrated the state in which the semiconductor optical device 10 (the layered portions 11-1 and 11-2 (11)) is aligned with the optical function device 20. For example, when the end surface 11b is formed using a cleavage, assume that there is variation in the cleavage position during the process of cleaving. In that case, with reference to the optical function device 20, when viewed from the opposite direction of the Z direction, there occurs a difference δx (variation, individual difference) in the positions of the alignment marks 15 in the X direction in a plurality of semiconductor optical devices 10. As a result, in the aligned state, there occurs a difference δy (variation, individual difference) in the positions of the alignment marks 15 in the Y direction. However, as illustrated in FIG. 1, the alignment marks 14 as well as the inclined portions 12b of the waveguides 12 are inclined by the same angle θ1 with respect to the X direction, and the alignment marks 14 are parallel to the inclined portions 12b. Hence, regardless of the position of the end surface 11b in the X direction, the end portions 14a of the two alignment marks 14 and the end surfaces 12d of the waveguides 12 in the X direction have the same intervals I3, I1, I2, I1, and I3 therebetween. Hence, according to the first embodiment, even when there occurs variation (individual variation) in the position of the end surface 11b in the X direction, the semiconductor optical device 10 and the optical function device 20 are aligned in such a way that the end portions 14a of the alignment marks 14 and the end portions 24a of the alignment marks 24 face in the X direction, that is, face each other. As a result, it becomes possible to attain the state in which the waveguides 12 and the waveguides 22 are aligned.

Regarding the optical function device 20 too, identical effects may be achieved. That is, since the alignment marks 24 as well as the end portions 22b of the waveguides 22 are inclined by the same angle θ2 with respect to the X direction, and the alignment marks 24 are parallel to the end portions 22b of the waveguides 22. Hence, regardless of the position of the end surface 21b in the X direction, the end portions 24a of the two alignment marks 24 and the end surfaces 22d of the waveguides 22 in the X direction have the same intervals I3, I1, I2, I1, and I3 therebetween. Hence, according to the first embodiment, even when there occurs variation (individual variation) in the position of the end surface 21b in the X direction, the semiconductor optical device 10 and the optical function device 20 are aligned in such a way that the end portions 14a of the alignment marks 14 and the end portions 24a of the alignment marks 24 face in the X direction, that is, face each other. As a result, it becomes possible to attain the state in which the waveguides 12 and the waveguides 22 are aligned.

Meanwhile, regarding the difference δx in the positions of the alignment marks 15 in the X direction, the difference δy in the positions of the alignment marks 15 in the Y direction, and the angle θ1; Equation (1) given below is established.

tan(θ1)=δy/δx (1)

Using the relationship given in Equation (1), from a difference δx in the positions of the alignment marks 15 in the X direction with respect to the reference position (for example, the position at which the distance to the end surface 21b in the Y direction is equal to d1), it becomes possible to estimate a difference δy in the positions of the end portions 15a with respect to the reference position of the alignment marks 15 in the Y direction (for example, the position in the Y direction of the end portion 25a of the alignment mark 25 in the Y direction). The position difference δy also represents the difference in the positions of the alignment marks 14 in the Y direction with respect to the reference position. Thus, for example, from the position information of the alignment marks 15 as obtained by performing image processing of the taken image, it is possible to estimate the positions of the alignment marks 14 in the Y direction. Hence, by performing such estimation of the positions, the alignment between the alignment marks 14 and the alignment marks 24 in the X direction may be complemented and may be put to use in speeding up the alignment in the X direction and achieving enhancement in the accuracy of the alignment.

FIG. 4 is an IV-IV cross-sectional view of FIG. 1. As illustrated in FIG. 4, the semiconductor optical device 10 includes a substrate 16 that expands while intersecting with the Z direction, and includes the layered portion 11 that is layered on the substrate 16. As illustrated in FIG. 4, in the layered portion 11, the depressed portions 11c are formed that are depressed with respect to the mesa 11d on both sides in the Y direction and that proportionally constitute the mesa 11d; a depressed portion 11f is formed that is not in alignment with the mesa 11d in the Y direction and that constitutes the corresponding alignment mark 14; and a depressed portion 11g is formed that constitutes the corresponding alignment mark 15. At an intermediate position in the mesa 11d in the Z direction, a core 12e is formed that constitutes the corresponding waveguide 12. Herein, the depressed portions 11c represent examples of a first depressed portion. The depressed portion 11f represents an example of a second depressed portion. The depressed portion 11g represents an example of a third depressed portion.

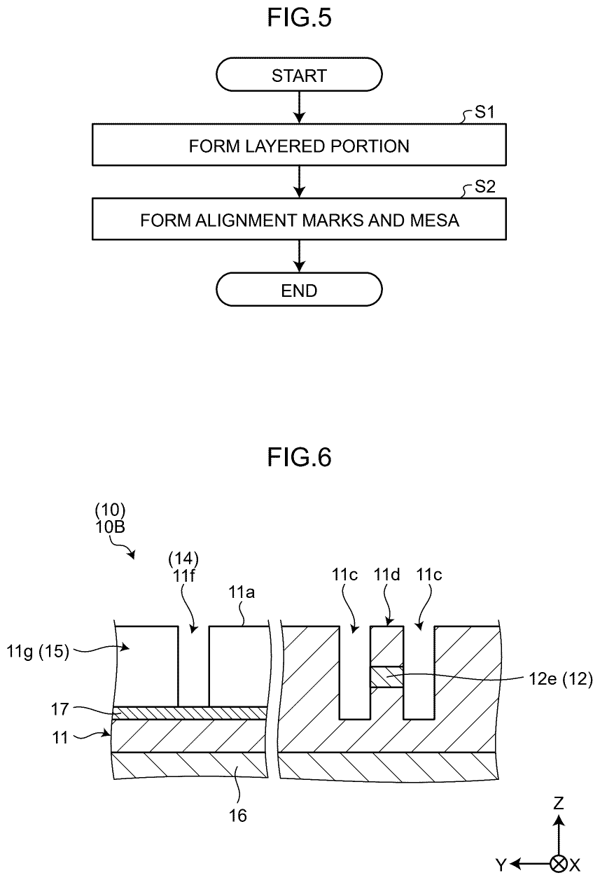

FIG. 5 is a flowchart for explaining some part of the sequence related to the formation of the layered portion 11 of the semiconductor optical device 10. As illustrated in FIG. 5, firstly, the layered portion 11 is formed on the substrate 16 (S1) and then the depressed portions 11c, the depressed portion 11f, and the depressed portion 11g are formed (S2). At S2, the depressed portions 11c, the depressed portion 11f, and the depressed portion 11g have the same depth from the top surface 11a in the Z direction. As a result of forming the depressed portions 11c, the depressed portion 11f, and the depressed portion 11g during the same process (S2), the waveguides 12 and the alignment marks 14 may be accurately aligned in a direction intersecting with the Z direction. Moreover, as compared to the case in which the depressed portions 11c, the depressed portion 11f, and the depressed portion 11g are formed during different processes, the time and efforts required for the manufacturing may be reduced.

Moreover, as illustrated in FIGS. 1 and 3, the alignment marks 14 and the alignment marks 15 are joined to each other. Thus, the alignment marks 14 and the alignment marks 15 are placed close to each other. As compared to the case in which the alignment marks 14 and the alignment marks 15 are separated from each other, for example, the space occupied by the alignment marks 14 and 15 may be narrowed and in turn the semiconductor optical device 10 may be configured in a smaller size. Since the imaging region of the alignment marks 14 and 15 may be narrowed, from an expanded image capturing the alignment marks 14 and 15, the positions of the alignment marks 14 may be identified with more accuracy; and the direction of extension of the alignment marks 15 may be identified with more accuracy. In turn, the orientation of the semiconductor optical device 10 may be identified with more accuracy. In an identical manner to the alignment marks 14 and 15, the alignment marks 24 and 25 too are joined to each other. Hence, regarding the alignment marks 24 and 25 too, for example, the space occupied by the alignment marks 24 and 25 may be narrowed and in turn the optical function device 20 may be configured in a smaller size. Since the imaging region of the alignment marks 24 and 25 may be narrowed, from an expanded image capturing the alignment marks 24 and 25, the positions of the alignment marks 24 may be identified with more accuracy; and the direction of extension of the alignment marks 25 may be identified with more accuracy. In turn, the orientation of the optical function device 20 may be identified with more accuracy.

As explained above, according to the first embodiment, as a result of performing alignment using the alignment marks 14 and 15 and the alignment marks 24 and 25, for example, the waveguides 12 and the waveguides 22 may be aligned with more accuracy regardless of the manufacturing variation.

FIG. 6 is a cross-sectional view, of an equivalent position to FIG. 4, of a semiconductor optical device 10B (10) according to a second embodiment. In the optical integrated device 100, the semiconductor optical device 10B may be embedded in place of the semiconductor optical device 10A according to the first embodiment. The semiconductor optical device 10B has an identical configuration to the configuration of the semiconductor optical device 10A, and enables achieving identical effects to the effects achieved in the semiconductor optical device 10A.

However, in the second embodiment, as illustrated in FIG. 6, the bottom portions of the depressed portions 11f and 11g, which constitute the alignment marks 14 and 15, are covered by a metal layer 17. According to such a configuration, for example, the alignment marks 14 and 15 may be visually confirmed with more ease. Since the alignment marks 14 and 15 become clearer in the taken image, the positions of the alignment marks 14 may be identified with more accuracy; and the direction of extension of the alignment marks 15 may be identified with more accuracy. In turn, the orientation of the semiconductor optical device 10 may be identified with more accuracy.

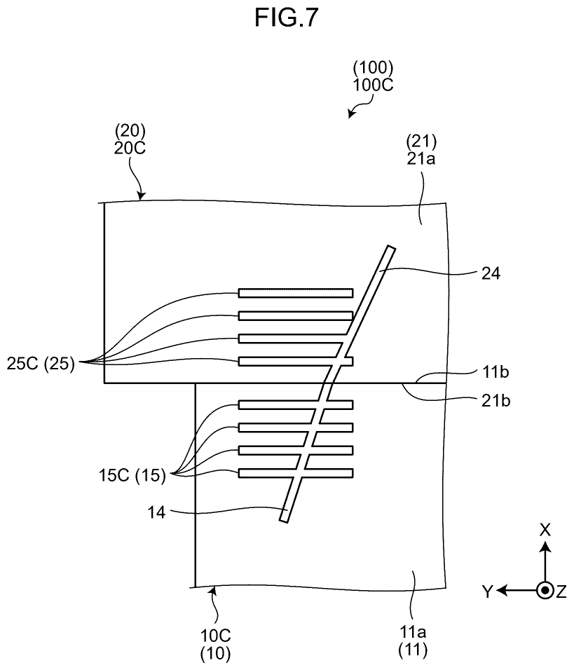

FIG. 7 is a planar view of some part of an optical integrated device 100C (100) according to a third embodiment. The optical integrated device 100C has an identical configuration to the configuration of the optical integrated device 100A, and enables achieving identical effects to the effects achieved in the optical integrated device 100A.

However, in the third embodiment, as illustrated in FIG. 7, a semiconductor optical device 10C (10) includes a plurality of alignment marks 15C (15) running parallel to each other. The alignment marks 15C are provided at predetermined intervals in the X direction. With such a configuration, even when there is variation in the cleavage position of the end surface 11b in the X direction, since some of the alignment marks 15C still remain intact, they may be used to align the semiconductor optical device 10C and an optical function device 20C. In an identical manner to the semiconductor optical device 10C, the optical function device 20C (20) too includes a plurality of alignment marks 25C (25) running parallel to each other. The alignment marks 25C are provided at predetermined intervals in the X direction. Hence, in the optical function device 20C too, it becomes possible to achieve identical effects to the effects achieved in the semiconductor optical device 10C.

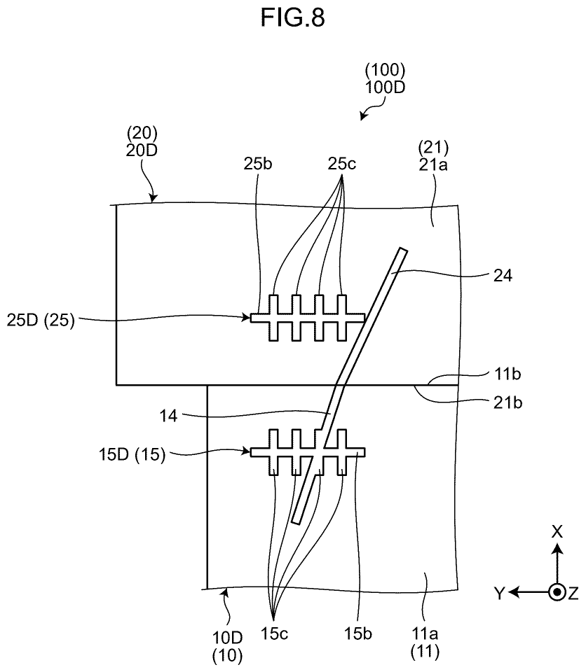

FIG. 8 is a planar view of some part of an optical integrated device 100D (100) according to a fourth embodiment. The optical integrated device 100D has an identical configuration to the configuration of the optical integrated device 100A, and enables achieving identical effects to the effects achieved in the optical integrated device 100A.

However, in the fourth embodiment, as illustrated in FIG. 8, an alignment mark 15D (15) in a semiconductor optical device 10D includes a portion 15b extending in the Y direction and includes a plurality of portions 15c formed at predetermined intervals (for example, constant intervals) in the Y direction and extending in the X direction. The portion 15b intersects with the portions 15c. In that case, using the portion 15b, the Y direction of the semiconductor optical device 10D may be identified, and in turn the orientation of the semiconductor optical device 10D may be identified. Moreover, using the portions 15c, the position of the alignment mark 15D in the Y direction may be identified with ease. Based on that, the positions of the end portions 14a of the alignment marks 14 may be geometrically calculated; and the alignment between the alignment marks 14 and the alignment marks 24 in the X direction may be complemented and may be put to use in speeding up the alignment in the X direction and achieving enhancement in the accuracy of the alignment. The portion 15b represents an example of a first extending portion, and the portions 15c represent examples of a second extending portion. In an identical manner to the alignment mark 15D, an alignment mark 25D (25) in an optical function device 20D (20) too includes a portion 25b extending in the Y direction and includes a plurality of portions 25c formed at predetermined intervals (for example, constant intervals) in the Y direction and extending in the X direction. Thus, in the optical function device 20D too, it becomes possible to achieve identical effects to the effects achieved as a result of using the alignment mark 15D in the semiconductor optical device 10D.

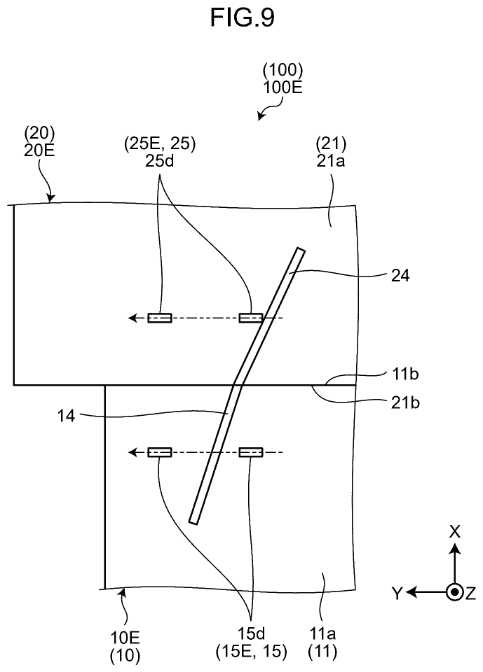

FIG. 9 is a planar view of some part of an optical integrated device 100E (100) according to a fifth embodiment. The optical integrated device 100E has an identical configuration to the configuration of the optical integrated device 100A, and enables achieving identical effects to the effects achieved in the optical integrated device 100A.

However, in the fifth embodiment, as illustrated in FIG. 9, an alignment mark 15E (15) in a semiconductor optical device 10E (10) includes a plurality of portions 15d separated in the Y direction. In that case, the Y direction may be identified from the portions 15d. In that case, since the alignment mark 15E may be formed in a smaller size, for example, the time and efforts required for manufacturing the alignment mark 15E may be reduced. In an identical manner to the alignment mark 15E, an alignment mark 25E (25) in an optical function device 20E (20) includes a plurality of portions 25d separated in the Y direction. Hence, in the optical function device 20E too, it becomes possible to achieve identical effects to the effects achieved as a result of using the alignment mark 15E in the semiconductor optical device 10E.

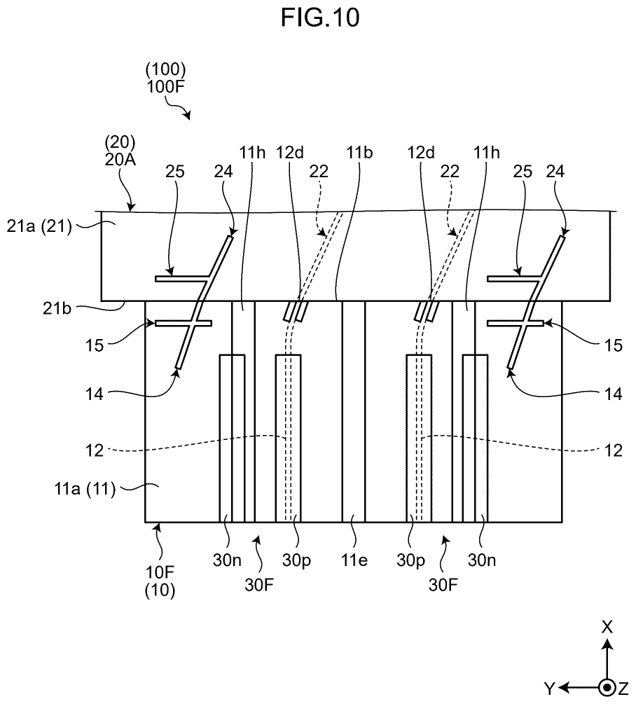

FIG. 10 is a planar view of an optical integrated device 100F (100) according to a sixth embodiment. The optical integrated device 100F includes a semiconductor optical device 10F (10) and includes the optical function device 20A identical to the first embodiment. The optical integrated device 100F has an identical configuration to the optical integrated device 100A, and enables achieving identical effects to the effects achieved in the optical integrated device 100A.

However, in a semiconductor optical device 10F, waveguide structure assemblies 30F operate as semiconductor light emitting devices such as semiconductor lasers. The semiconductor light emitting devices output lights from the end surfaces 12d of the waveguides 12. That is, the semiconductor optical device 10F according to the sixth embodiment is configured as a semiconductor light emitting device array. The waveguides 12 represent active waveguides. When the semiconductor light emitting device is a semiconductor laser, each waveguide structure assembly 30 includes a reflective coating constituting a laser resonator. When the semiconductor light emitting device is a semiconductor laser of the DFB type, each waveguide structure assembly 30 includes a diffraction grating meant for defining the laser emission wavelength. Meanwhile, each waveguide structure assembly 30F includes an electrode 30p functioning as the P-side electrode, and includes an electrode 30n functioning as the N-side electrode. Each electrode 30n is disposed in the range spanning from the bottom surface of a depressed portion 11h to the top surface 11a via the side surface.

While certain embodiments and modification examples have been described, these embodiments and modification examples have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure. Moreover, regarding the constituent elements, the specifications about the configurations and the shapes (structure, type, direction, shape, size, length, width, thickness, height, number, arrangement, position, material, etc.) may be suitably modified.

According to the present disclosure, it becomes possible to provide a semiconductor optical device that includes new and improved alignment marks, and to obtain a semiconductor optical device manufacturing method.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical integrated device comprising:
a semiconductor optical device; and
an optical function device, wherein
the semiconductor optical device includes:
a first layered portion including therein a first waveguide extending in a direction intersecting with a first direction;
a first top surface positioned at a first end portion of the first layered portion in the first direction, the first top surface intersecting with the first direction and being oriented in the first direction;
a first end surface positioned at a second end portion of the first layered portion in a second direction intersecting with the first direction, the first end surface intersecting with the second direction and being oriented in the second direction;
a plurality of first end portions of the first waveguide, the plurality of first end portions being exposed at a plurality of positions on the first end surface and separated from each other in a third direction intersecting with the first direction and the second direction;
two first position identification marks provided on the first top surface and separated from each other in the third direction such that the two first position identification marks extend in parallel to a direction of extension of the first end portions at the first end surface from an end portion of the first top surface in the second direction and are positioned in between the plurality of first end portions when viewed from opposite direction of the first direction, and a predetermined relative positional relationship is established with the plurality of first end portions in the third direction; and
a first orientation identification mark provided on the first top surface and configured to enable identification of the third direction in the first layered portion when viewed from an opposite direction of the first direction, and
the optical function device includes:
a second layered portion including therein a second waveguide extending in a direction intersecting with the first direction;
a second top surface positioned at an end portion of the second layered portion in the first direction, the second top surface intersecting with the first direction and being oriented in the first direction;
a second end surface that is positioned at a third end portion of the second layered portion in an opposite direction of the second direction, the second end surface intersecting with the second direction and being oriented in the opposite direction of the second direction;
a plurality of second end portions of the second waveguide, the plurality of second end portions being exposed at a plurality of positions of the second end surface and separated from each other in the third direction such that intervals therebetween correspond to intervals between the plurality of first end portions;
two second position identification marks provided on the second top surface and separated from each other in the third direction such that the two second position identification marks extend in parallel to a direction of extension of the second end portions at the second end surface from an end portion of the second top surface in the opposite direction of the second direction and are positioned in between the plurality of second end portions when viewed from an opposite direction of the first direction, and relative positional relationship established therebetween is same as relative positional relationship established between the plurality of first end portions and the two first position identification marks in the third direction; and
a second orientation identification mark provided on the second top surface and configured to enable identification of the third direction in the second layered portion when viewed from the opposite direction of the first direction.

2. The optical integrated device according to claim 1, wherein the first end portions and the first position identification marks are inclined by same angle with respect to the second direction.

3. The optical integrated device according to claim 1, wherein the second end portions and the second position identification marks are inclined by same angle with respect to the second direction.

4. The optical integrated device according to claim 3, wherein
the first end portions and the first position identification marks are inclined by a first angle with respect to the second direction, and
the second end portions and the second position identification marks are inclined with respect to the second direction by a second angle that is different from the first angle.

5. The optical integrated device according to claim 1, wherein the first layered portion includes:
a mesa including the first waveguide;
first depressed portions formed adjacent to both sides of the mesa in the third direction and depressed in the opposite direction of the first direction; and
second depressed portions depressed in the opposite direction of the first direction up to a same depth as a depth of the first depressed portions and constituting the first position identification marks.

6. The optical integrated device according to claim 5, wherein bottom portions of the second depressed portions are covered by a metal layer.

7. The optical integrated device according to claim 5, wherein the first layered portion includes a third depressed portion depressed for the same depth as the first depressed portions and constituting the first orientation identification mark.

8. The optical integrated device according to claim 7, wherein a bottom portion of the third depressed portion is covered by a metal layer.

9. The optical integrated device according to claim 1, wherein the first orientation identification mark includes a plurality of marks separated in the second direction.

10. The optical integrated device according to claim 1, wherein the first orientation identification mark includes a first extending portion extending in the third direction.

11. The optical integrated device according to claim 10, wherein the first orientation identification mark includes a plurality of second extending portions extending in the second direction and separated in the third direction.

12. The optical integrated device according to claim 1, wherein the first orientation identification mark includes a plurality of portions separated in the third direction.

13. The optical integrated device according to claim 1, wherein the first waveguide is an active waveguide.

14. The optical integrated device according to claim 13, wherein the first waveguide includes two waveguides optically connected via a folded waveguide.

15. The optical integrated device according to claim 14, wherein the folded waveguide is a passive waveguide.

16. The optical integrated device according to claim 15, comprising a plurality of waveguide structure assemblies each of which includes the folded waveguide and the two first waveguides which are optically connected via the folded waveguide.

17. The optical integrated device according to claim 13, comprising a semiconductor optical amplifier or a semiconductor light emitting device including the active waveguide.

18. A semiconductor optical device comprising:
a first layered portion including therein a first waveguide extending in a direction intersecting with a first direction;
a first top surface positioned at a first end portion of the first layered portion in the first direction, the first top surface intersecting with the first direction and being oriented in the first direction;
a first end surface positioned at a second end portion of the first layered portion in a second direction intersecting with the first direction, the first end surface intersecting with the second direction and being oriented in the second direction;
a plurality of first end portions of the first waveguide, the plurality of first end portions being exposed at a plurality of positions on the first end surface and separated from each other in a third direction intersecting with the first direction and the second direction;
two first position identification marks provided on the first top surface and separated from each other in the third direction such that the two first position identification marks extend in parallel to a direction of extension of the first end portions at the first end surface from an end portion of the first top surface in the second direction and are positioned in between the plurality of first end portions when viewed from opposite direction of the first direction, and a predetermined relative positional relationship is established with the plurality of first end portions in the third direction; and
a first orientation identification mark provided on the first top surface and configured to enable identification of the third direction in the first layered portion when viewed from an opposite direction of the first direction.

19. A method for manufacturing a semiconductor optical device for an optical integrated device including the semiconductor optical device and an optical function device, wherein
the semiconductor optical device includes:
a first layered portion including therein a first waveguide extending in a direction intersecting with a first direction;
a first top surface positioned at a first end portion of the first layered portion in the first direction, the first top surface intersecting with the first direction and being oriented in the first direction;
a first end surface positioned at a second end portion of the first layered portion in a second direction intersecting with the first direction, the first end surface intersecting with the second direction and being oriented in the second direction;
a plurality of first end portions of the first waveguide, the plurality of first end portions being exposed at a plurality of positions on the first end surface and separated from each other in a third direction intersecting with the first direction and the second direction;
two first position identification marks provided on the first top surface and separated from each other in the third direction such that the two first position identification marks extend in parallel to a direction of extension of the first end portions at the first end surface from an end portion of the first top surface in the second direction and are positioned in between the plurality of first end portions when viewed from opposite direction of the first direction, and a predetermined relative positional relationship is established with the plurality of first end portions in the third direction; and
a first orientation identification mark provided on the first top surface and configured to enable identification of the third direction in the first layered portion when viewed from an opposite direction of the first direction, and
the optical function device includes:
a second layered portion including therein a second waveguide extending in a direction intersecting with the first direction;
a second top surface positioned at an end portion of the second layered portion in the first direction, the second top surface intersecting with the first direction and being oriented in the first direction;
a second end surface that is positioned at a third end portion of the second layered portion in an opposite direction of the second direction, the second end surface intersecting with the second direction and being oriented in the opposite direction of the second direction;
a plurality of second end portions of the second waveguide, the plurality of second end portions being exposed at a plurality of positions of the second end surface and separated from each other in the third direction such that intervals therebetween correspond to intervals between the plurality of first end portions;
two second position identification marks provided on the second top surface and separated from each other in the third direction such that the two second position identification marks extend in parallel to a direction of extension of the second end portions at the second end surface from an end portion of the second top surface in the opposite direction of the second direction and are positioned in between the plurality of second end portions when viewed from an opposite direction of the first direction, and relative positional relationship established therebetween is same as relative positional relationship established between the plurality of first end portions and the two first position identification marks in the third direction; and
a second orientation identification mark provided on the second top surface and configured to enable identification of the third direction in the second layered portion when viewed from the opposite direction of the first direction,
the semiconductor optical device manufacturing method comprising:
layering the first layered portion on a substrate; and
forming, in the first layered portion,
first depressed portions that are adjacent to both sides of a mesa including the first waveguide in the third direction and that are depressed in an opposite direction of the first direction, and
second depressed portions that are depressed in the opposite direction of the first direction up to a same depth as a depth of the first depressed portions and that constitute the first position identification marks.
